(19) United States
(12) Patent Application Publication
(10) Pub. No.: US 2026/0231437 A1
(43) Pub. Date: Aug. 6, 2026

(54) MEMORY DEVICE AND MANUFACTURING METHOD THEREOF, AND ELECTRONIC DEVICE

(71) Applicant: PEKING UNIVERSITY, Beijing (CN)

(72) Inventors: Zongwei WANG, Beijing (CN); Yimao CAI, Beijing (CN); Yingtong JI, Beijing (CN); Haisu ZHANG, Beijing (CN)

(73) Assignee: PEKING UNIVERSITY, Beijing (CN)

(21) Appl. No.: 19/422,205

(22) Filed: Dec. 16, 2025

(30) Foreign Application Priority Data
Feb. 6, 2025 (CN) 202510130707.2

(51) Int. Cl. H10B 63/00

(52) U.S. Cl. CPC H10B 63/30

(57) ABSTRACT

Memory device, manufacturing method thereof, and electronic device are provided. The memory device includes: memory cells arranged on substrate and arranged at intervals perpendicular to the substrate, each memory cell including gating transistor and resistive switching component, gating transistor including horizontal semiconductor layer extending along first direction, resistive switching component including horizontal semiconductor layer, and resistive switching layer and electrode layer sequentially arranged away from the horizontal semiconductor layer in first direction; source lines extending along second direction and arranged at intervals along third direction, source line being arranged on a side of horizontal semiconductor layer away from resistive switching layer along first direction; word line arranged in third direction and intersecting horizontal semiconductor layers of gating transistors arranged in third direction; and bit line arranged along third direction and connected to electrode layers of resistive switching components arranged along third direction.

### CROSS-REFERENCE TO RELATED APPLICATION

This application claims priority under 35 U.S.C. §119 to Chinese Patent Application No. 202510130707.2, filed with CNIPA on February 06, 2025, entitled “MEMORY DEVICE AND MANUFACTURING METHOD THEREOF, AND ELECTRONIC DEVICE”, the entire contents of which are incorporated herein by reference.

### TECHNICAL FIELD

The present application relates to the field of integrated circuit technologies, and in particular, to a memory device, a manufacturing method thereof, and an electronic device.

### BACKGROUND

According to Moore's law, as the number of semiconductor components in a semiconductor memory doubles, the performance of the semiconductor memory doubles accordingly. To improve the performance of the semiconductor memory, the feature size of the semiconductor components is ceaselessly reduced and the integration level of the semiconductor components is continuously increased. However, as semiconductor process nodes turn smaller and smaller, the size reduction of the semiconductor memory is challenging, the cost and complexity of manufacture of the semiconductor memory are increased, and meanwhile, the performance of the semiconductor memory improves slowly, making it difficult to realize higher storage density.

In the field of integrated circuits, integrating the semiconductor components further based on a third dimension provides a new direction for continuation of Moore's law.

### SUMMARY

In view of the problems in the prior art, a memory device, a manufacturing method thereof, and an electronic device are provided.

In order to achieve the above object, in a first aspect, the present disclosure provides a memory device, including:

memory cells arranged on a substrate, where the memory cells are arranged at intervals along a direction perpendicular to the substrate, and each of the memory cells includes a gating transistor and a resistive switching component; the gating transistor includes a horizontal semiconductor layer extending along a first direction parallel to the substrate, and the resistive switching component includes the horizontal semiconductor layer, and a resistive switching layer and an electrode layer which are sequentially arranged away from the horizontal semiconductor layer in the first direction;

source lines each extending along a second direction parallel to the substrate and arranged at intervals along a third direction perpendicular to the substrate, where the first direction intersects the second direction, and along the first direction, the source line is arranged on a side of the horizontal semiconductor layer away from the resistive switching layer;

a word line arranged in the third direction, where the word line intersects the horizontal semiconductor layers of the gating transistors arranged along the third direction; and

a bit line arranged along the third direction, where the bit line is connected to the electrode layers of the resistive switching components arranged along the third direction.

Optionally, in the memory cells arranged along the third direction, the resistive switching layers of the resistive switching components are sequentially connected.

Optionally, the resistive switching layer surrounds a circumferential surface of the electrode layer.

Optionally, the gating transistor includes:

a first source/drain, a semiconductor channel, and a second source/drain, where the first source/drain, the semiconductor channel, and the second source/drain are sequentially arranged at the horizontal semiconductor layer along a direction away from the source line;

a gate dielectric layer arranged between the word line and the semiconductor channel, where in a plane perpendicular to the first direction, the gate dielectric layer surrounds the semiconductor channel; and

a gate, where in a plane perpendicular to the first direction, the gate surrounds the gate dielectric layer, and the gate is connected to the word line.

Optionally, the memory cells are arranged along the first direction and the second direction; and

along the first direction, one side of the bit line is connected to a first memory cell, the other side of the bit line is connected to a second memory cell, and the first memory cell and the second memory cell are in mirror symmetry with respect to the bit line.

Optionally, in the first direction, the first memory cell and the second memory cell are located on both sides of the source line, and share the same source line.

In a second aspect, the present disclosure provides a manufacturing method of a memory device, including:

providing a substrate, and forming alternating insulating layers and semiconductor material layers on the substrate;

patterning the alternating insulating layers and semiconductor material layers, where the semiconductor material layers form horizontal semiconductor layers and source lines, the horizontal semiconductor layers each extend along a first direction, the source lines each extend along a second direction, the first direction and the second direction are parallel to the substrate, and the first direction intersects the second direction; where along the first direction, at least one end of the horizontal semiconductor layer is connected to the source line, and the horizontal semiconductor layer includes a first source/drain, a semiconductor channel, and a second source/drain which are sequentially arranged in a direction away from the source line;

removing a part of the insulating layers to expose the semiconductor channels;

forming gate dielectric layers to cover the semiconductor channels;

forming gates and word lines, where the gates cover the gate dielectric layers and form gating transistors together with the horizontal semiconductor layers, the word lines are perpendicularly arranged on the substrate along a third direction, and the word lines intersect the semiconductor channels of the gating transistors arranged along the third direction, and are connected to the gates of the gating transistors;

sequentially forming a resistive switching layer and an electrode layer on a side of each horizontal semiconductor layer away from the source line, where the resistive switching layer, the electrode layer, and the horizontal semiconductor layer jointly form a resistive switching component, and the gating transistor and the resistive switching component form a memory cell; and

forming bit lines extending along the third direction, where the bit lines are connected to the electrode layers of the resistive switching components arranged along the third direction.

Optionally, sequentially forming the resistive switching layer and the electrode layer on the side of each horizontal semiconductor layer away from the source line includes:

forming a first trench on a side of the second source/drain of the horizontal semiconductor layer away from the source line, the first trench being arranged on the substrate along the third direction;

forming the resistive switching layer, the resistive switching layer covering a side wall of the first trench; and

forming the electrode layer, the electrode layer covering an inner side wall of the resistive switching layer and filling an unfilled region of the first trench.

Optionally, after the horizontal semiconductor layer and the source lines are formed, along the first direction, two ends of the horizontal semiconductor layer are respectively connected to the source lines; and the manufacturing method includes:

etching the alternating insulating layers and horizontal semiconductor layers to form the first trench penetrating through the alternating insulating layers and horizontal semiconductor layers, the first trench dividing the horizontal semiconductor layer into a first section and a second section which are spaced apart along the first direction;

where the first section is configured to form the first memory cell, the second section is configured to form the second memory cell, and the first memory cell and the second memory cell are in mirror symmetry with respect to the bit line.

In a third aspect, the present disclosure provides an electronic device, including the memory device according to the first aspect, or a memory device manufactured by the manufacturing method of the memory device according to the second aspect.

In the memory device, the manufacturing method thereof, and the electronic device according to the present disclosure, the horizontal semiconductor layer of the gating transistor extends along the first direction, and the horizontal arrangement of the gating transistor can reduce an occupied area of the gating transistor and reduce a feature size of the gating transistor. The resistive switching component includes the horizontal semiconductor layer, the resistive switching layer, and the electrode layer which are sequentially arranged along the first direction, and the gating transistor and the resistive switching component share the horizontal semiconductor layer, so that a feature size of the memory cell can be reduced, and integration density of the memory cells can be improved. Meanwhile, the source line extends along the second direction, the source line is connected to the side of the horizontal semiconductor layer away from the resistive switching layer, the word line extends along the third direction, the word line intersects the horizontal semiconductor layer of the gating transistor, the bit line extends along the third direction, and the bit line is connected to the electrode layers of the resistive switching components arranged along the third direction. In this way, the memory cells can be integrated using the third direction perpendicular to the substrate, and integration density of the memory device is enhanced.

### BRIEF DESCRIPTION OF THE DRAWINGS

In order to illustrate the technical solutions in the embodiments of the present application or the prior art more clearly, the drawings required for describing the embodiments or the prior art will be described briefly. Apparently, the following described drawings are merely for some embodiments of the present application, and other drawings can be derived from these drawings by those of ordinary skill in the art without any creative effort.

FIG. 1 is a top view of a memory device according to some embodiments of the present application;

FIG. 2 is a schematic cross-sectional view taken along line A-A in FIG. 1;

FIG. 3 is a schematic cross-sectional view taken along line B-B in FIG. 1;

FIG. 4 is a top view of a memory device according to some embodiments of the present application;

FIG. 5 is a schematic cross-sectional view taken along line A-A in FIG. 4;

FIG. 6 is a schematic cross-sectional view taken along line B-B in FIG. 4;

FIG. 7 is a process flowchart of a manufacturing method of a memory device according to some embodiments of the present application;

FIG. 8 is a top view after alternating insulating layers and semiconductor material layers are formed on a substrate in some embodiments of the present application;

FIG. 9 is a schematic cross-sectional view taken along line A-A in FIG. 8;

FIG. 10 is a schematic cross-sectional view taken along line B-B in FIG. 8;

FIG. 11 is a top view after the alternating insulating layers and semiconductor material layers are patterned in some embodiments of the present application;

FIG. 12 is a schematic cross-sectional view taken along line A-A in FIG. 11;

FIG. 13 is a schematic cross-sectional view taken along line B-B in FIG. 11;

FIG. 14 is a top view after a first dielectric layer is formed in some embodiments of the present application;

FIG. 15 is a schematic cross-sectional view taken along line A-A in FIG. 14;

FIG. 16 is a schematic cross-sectional view taken along line B-B in FIG. 14;

FIG. 17 is a top view after a semiconductor channel is exposed in some embodiments of the present application;

FIG. 18 is a schematic cross-sectional view taken along line A-A in FIG. 17;

FIG. 19 is a schematic cross-sectional view taken along line B-B in FIG. 17;

FIG. 20 is a top view after a gating transistor and a word line are formed in some embodiments of the present application;

FIG. 21 is a schematic cross-sectional view taken along line A-A in FIG. 20;

FIG. 22 is a schematic cross-sectional view taken along line B-B in FIG. 20;

FIG. 23 is a top view after a first trench is formed in some embodiments of the present application;

FIG. 24 is a schematic cross-sectional view taken along line A-A in FIG. 23;

FIG. 25 is a schematic cross-sectional view taken along line B-B in FIG. 23;

FIG. 26 is a top view after a resistive switching component and a bit line are formed in some embodiments of the present application;

FIG. 27 is a schematic cross-sectional view taken along line A-A in FIG. 26; and

FIG. 28 is a schematic cross-sectional view taken along line B-B in FIG. 26.

Reference signs are explained as follows:

100: memory device; 10: substrate; 20: memory cell; 21: gating transistor; 211: first source/drain; 212: semiconductor channel; 213: second source/drain; 214: gate dielectric layer; 215: gate; 22: resistive switching component; 221: resistive switching layer; 222: electrode layer; 30: source line; 40: word line; 50: bit line; 61: insulating layer; 62: semiconductor material layer; 63: horizontal semiconductor layer; 64. etch stop layer; 65: first dielectric layer; 101: first trench; 120: first memory cell; 220: second memory cell.

### DETAILED DESCRIPTION

To facilitate an understanding of the present application, the present application is described more fully hereinafter with reference to the accompanying drawings. Preferred embodiments of the present application are shown in the drawings. However, the present application may be implemented in many different forms and is not limited to the embodiments set forth herein. Rather, these embodiments are provided to make the disclosure of the present application more thorough and complete.

Unless defined otherwise, all technical and scientific terms used herein have the same meanings as are commonly understood by those skilled in the art. The terms used herein in the specification of the present application are for the purpose of describing specific embodiments only but not intended to limit the present application.

A resistive random access memory (RRAM) has the advantages of simple structure, flexible design, small feature size, fast read-write speed, and compatibility with a complementary metal-oxide-semiconductor (CMOS) process, and is considered as one of the next generation memory technologies with the most integration potential.

In related technologies, a memory array based on RRAM cells can solve the problem of current leakage of the RRAM cells by adopting a one transistor one resistor (1T1R) architecture. However, in the 1T1R architecture of the related technology, the feature size of gating transistors is 6F², which limits scalability of the RRAM cells, and the feature size of the RRAM cells is difficult to be further reduced. Moreover, due to a thermal budget limitation of the CMOS process, the existing RRAM cells with the 1T1R architecture cannot realize further enhancement in density through three-dimensional stacking by using a third dimension, severely impeding high-density integration of the RRAMs.

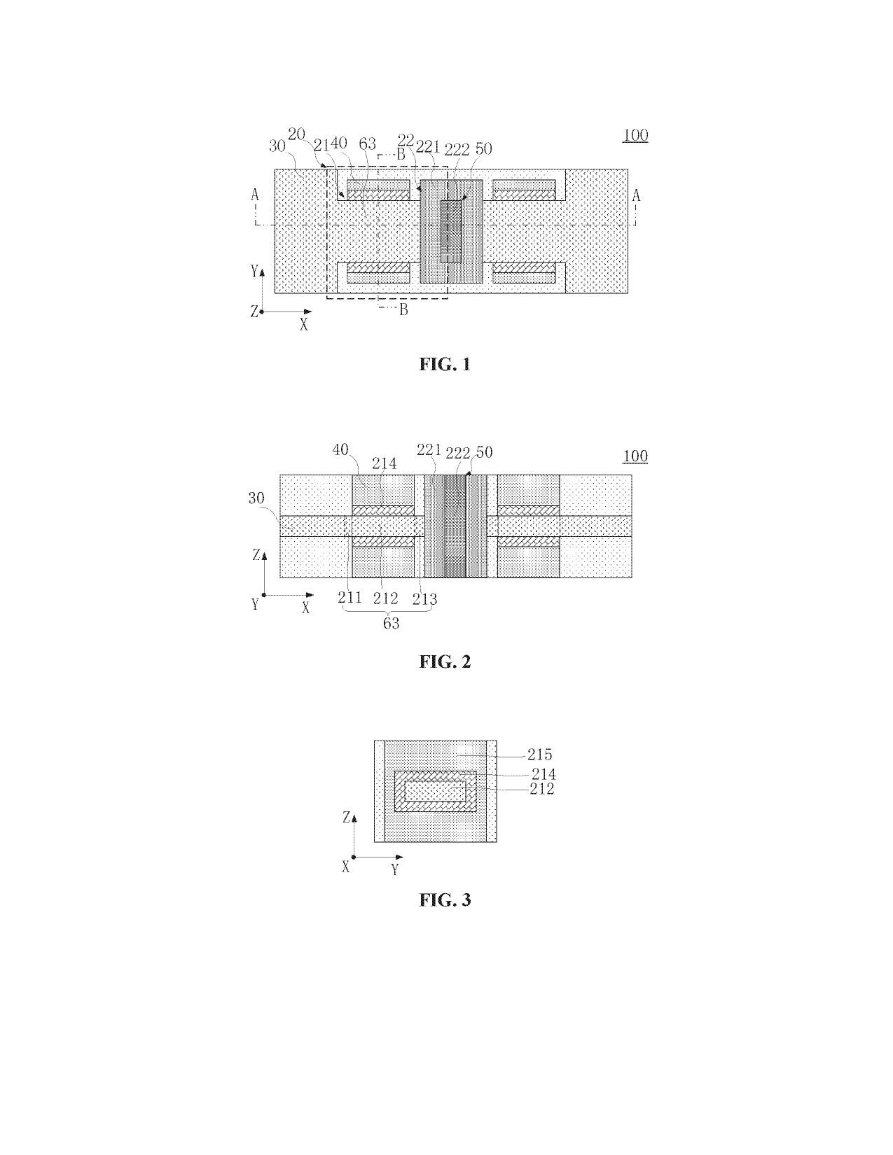

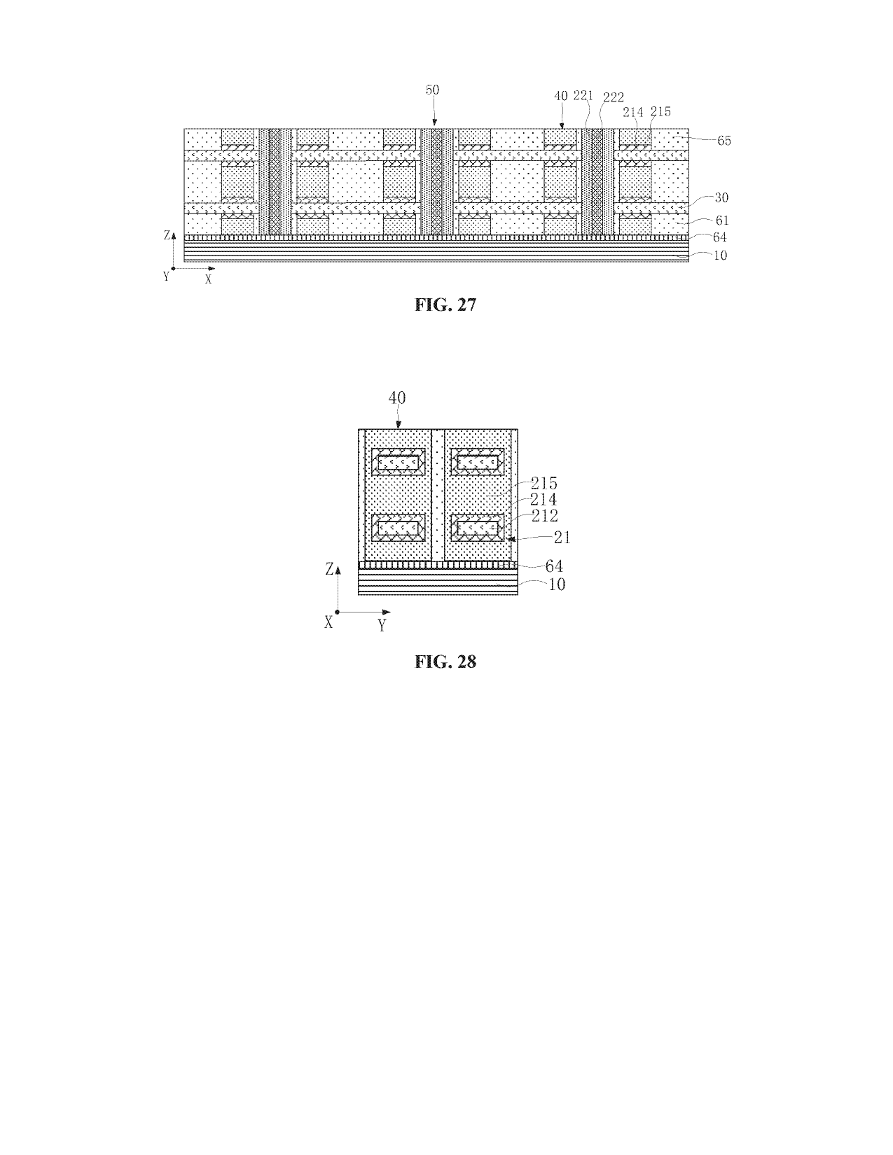

According to an exemplary embodiment, the present disclosure provides a memory device. Reference can be made to FIG. 1, FIG. 2, and FIG. 3, and further to FIG. 26, FIG. 27, and FIG. 28. A memory device 100 includes memory cells 20, source lines 30, word lines 40, and bit lines 50. The memory cells 20 are arranged on a substrate 10. The memory cells 20 are arranged at intervals along a direction perpendicular to the substrate 10. Each of the memory cells 20 includes a gating transistor 21 and a resistive switching component 22. The gating transistor 21 includes a horizontal semiconductor layer 63 extending along a first direction X parallel to the substrate 10. The resistive switching component 22 includes the horizontal semiconductor layer 63, and a resistive switching layer 221 and an electrode layer 222 which are sequentially arranged away from the horizontal semiconductor layer 63 along the first direction X. The source lines 30 each extend along a second direction Y parallel to the substrate 10, and are arranged at intervals along a third direction Z perpendicular to the substrate 10, where the first direction X intersects the second direction Y. Along the first direction X, the source line 30 is arranged on a side of the horizontal semiconductor layer 63 away from the resistive switching layer 221. The word lines 40 are arranged in the third direction Z, and the word lines 40 intersect the horizontal semiconductor layers 63 of the gating transistors 21 arranged along the third direction Z. The bit lines 50 are arranged along the third direction Z, and the bit lines 50 are connected to the electrode layers 222 of the resistive switching components 22 arranged along the third direction Z.

In the memory device 100 according to the embodiment, the horizontal semiconductor layer 63 of the gating transistor 21 extends along the first direction, and the horizontal arrangement of the gating transistor 21 can reduce an occupied area of the gating transistor and reduce a feature size of the gating transistor 21. The resistive switching component 22 includes the horizontal semiconductor layer 63, the resistive switching layer 221, and the electrode layer 222 which are sequentially arranged along the first direction X, and the gating transistor 21 and the resistive switching component 22 share the horizontal semiconductor layer 63, so that a feature size of the memory cell 20 can be reduced, and integration density of the memory cells 20 can be improved. Meanwhile, the source line 30 extends along the second direction Y, the source line 30 is connected to the side of the horizontal semiconductor layer 63 away from the resistive switching layer 221; the word line 40 extends along the third direction Z, the word line 40 intersects the horizontal semiconductor layer 63 of the gating transistor 21; the bit line 50 extends along the third direction Z, and the bit line 50 is connected to the electrode layers 222 of the resistive switching components 22 arranged along the third direction Z. Hence, the memory cells 20 can be integrated using the third direction Z perpendicular to the substrate 10, and integration density of the memory device 100 is enhanced.

In some embodiments, referring to FIG. 1, FIG. 2, and FIG. 3, in the memory cells 20 arranged along the third direction Z, the resistive switching layers 221 of the resistive switching components 22 are sequentially connected. For multiple memory cells 20 arranged along the third direction Z, the resistive switching layers 221 of the resistive switching components 22 of the multiple memory cells 20 are sequentially connected, and the resistive switching layers 221 are perpendicularly arranged on the substrate 10 along the third direction Z. The resistive switching layer 221 includes a resistive switching region and a non-resistive switching region sequentially arranged along the third direction Z. The gating transistor 21 of each memory cell 20 is correspondingly connected to one resistive switching region. In this way, it facilitates a reduction of manufacturing difficulty of the memory device 100, the production cost can be reduced, and the product yield can be enhanced.

In some embodiments, referring to FIG. 1, FIG. 2, and FIG. 3, the resistive switching layer 22 surrounds a circumferential surface of the electrode layer 222. In other words, in a plane parallel to the substrate 10, the circumferential surface of the electrode layer 222 is covered by the resistive switching layer 221. A contact area between the resistive switching layer 221 and the electrode layer 222 of the resistive switching component 22 is larger, so that a driving current of the resistive switching layer 221 can be decreased, and the resistive switching layer 221 can be driven by a smaller driving current to change a resistance value of the resistive switching layer 221, thereby completing a read-write operation. In this way, the memory cell 20 may have a smaller feature size, which facilitates further miniaturization and small size of the memory device 100.

It may be understood that in some other embodiments, the resistive switching layer 221 may cover only a side wall of the electrode layer 222 near the horizontal semiconductor layer 63. Alternatively, in the plane parallel to the substrate 10, the resistive switching layer 221 may cover a part of the circumferential surface of the electrode layer 222.

In some embodiments, referring to FIG. 1, FIG. 2, and FIG. 3, the gating transistor 21 includes: a first source/drain 211, a semiconductor channel 212, a second source/drain 213, a gate dielectric layer 214, and a gate 215. The first source/drain 211, the semiconductor channel 212, and the second source/drain 213 are sequentially arranged at the horizontal semiconductor layer 63 along a direction away from the source line 30. The gate dielectric layer 214 is arranged between the word line 40 and the semiconductor channel 212. In a plane perpendicular to the first direction X, the gate dielectric layer 214 surrounds the semiconductor channel 212. In a plane perpendicular to the first direction X, the gate 215 surrounds the gate dielectric layer 214. The gate 215 is connected to the word line 40.

In the memory device 100 according to the embodiment, the gating transistor 21 is a gate-all-around transistor with a horizontal channel, and the gating transistor 21 may have a smaller feature size, which is beneficial to further reducing the size of the memory cell 20, improving the integration density of the memory cells 20, and enhancing a utilization rate of a usable area of the substrate 10.

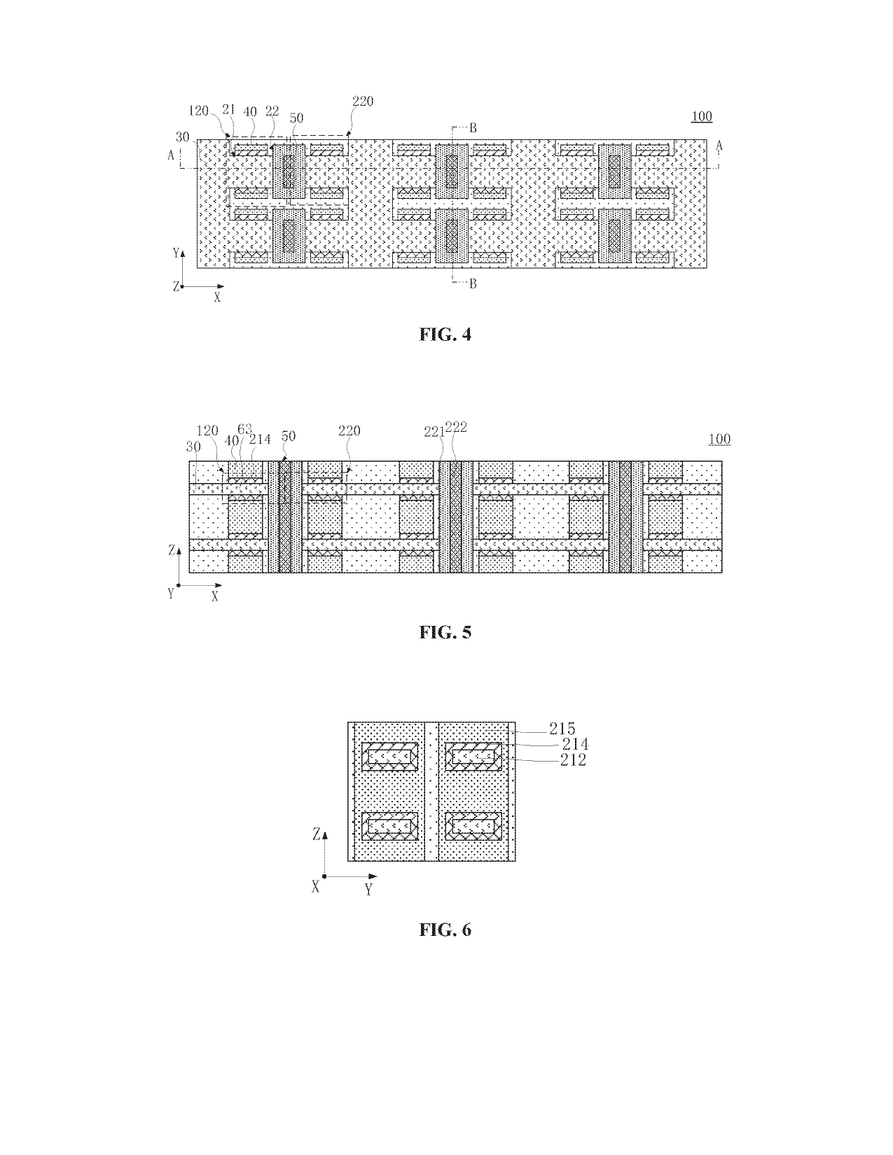

In some embodiments, referring to FIG. 4, FIG. 5, and FIG. 6, the memory cells 20 are arranged along the first direction X and the second direction Y. That is, the memory cells 20 are arranged into a three-dimensional array on the substrate 10 in the first direction X, the second direction Y, and the third direction Z. The three-dimensional array includes multiple layers of memory cells 20 arranged along the third direction Z, each layer of memory cells 20 including multiple rows of memory cells 20, each row extending along the first direction X, and multiple columns of memory cells 20, each column extending along the second direction Y. In each layer of memory cells 20, the gating transistors 21 of each column of memory cells 20 arranged in the second direction Y share the source line 30.

In the memory device 100 in the embodiment, the usable area of the substrate 10 is fully utilized to realize three-dimensional integration of the memory cells 20 with the 1S1R architecture, and the three-dimensional array of the memory cells 20 is integrated on the substrate 10.

In some embodiments, referring to FIG. 4, FIG. 5, and FIG. 6, along the first direction X, one side of the bit line 50 is connected to a first memory cell 120, the other side of the bit line is connected to a second memory cell 220, and the first memory cell 120 and the second memory cell 220 are in mirror symmetry with respect to the bit line 50. Thus, the first memory cell 120 and the second memory cell 220 on both sides of the bit line 50 share the same bit line 50, which further enhances the integration density of the memory cells 20, improves the utilization rate of the usable area of the substrate 10, and meanwhile can reduce the manufacturing difficulty of the memory device 100, save manufacturing processes, and be beneficial to reducing the production cost and increasing the product yield.

In some embodiments, referring to FIG. 4, FIG. 5, and FIG. 6, along the first direction X, the first memory cell 120 and the second memory cell 220 located on both sides of the source line 30 share the same source line 30. In each layer of memory cells 20, one column of first memory cells 120 and one column of second memory cells 220 located on both sides of the source line 30 share the same source line 30, which further enhances the integration density of the memory cells 20, improves the utilization rate of the usable area of the substrate 10, and meanwhile can reduce the manufacturing difficulty of the memory device 100, save the manufacturing processes, and be beneficial to reducing the production cost and increasing the product yield.

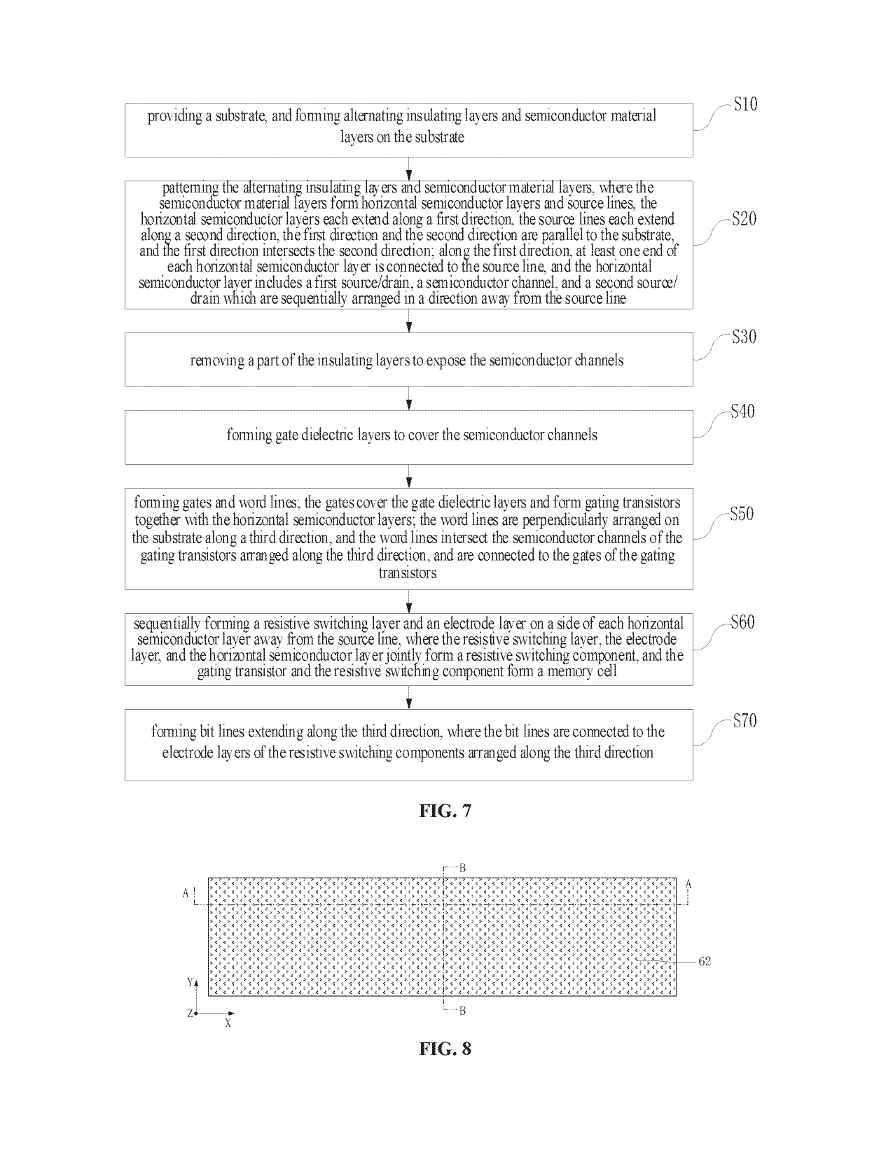

According to an exemplary embodiment, a manufacturing method of a memory device is provided. As shown in FIG. 7, the manufacturing method of the memory device includes the following steps S10 to S70.

Step S10 includes: providing a substrate, and forming alternating insulating layers and semiconductor material layers on the substrate.

Step S20 includes: patterning the alternating insulating layers and semiconductor material layers, where the semiconductor material layers form horizontal semiconductor layers and source lines, the horizontal semiconductor layers each extend along a first direction, the source lines each extend along a second direction, the first direction and the second direction are parallel to the substrate, and the first direction intersects the second direction. Along the first direction, at least one end of each horizontal semiconductor layer is connected to the source line, and the horizontal semiconductor layer includes a first source/drain, a semiconductor channel, and a second source/drain which are sequentially arranged in a direction away from the source line.

Step S30 includes: removing a part of the insulating layers to expose the semiconductor channels.

Step S40 includes: forming gate dielectric layers to cover the semiconductor channels.

Step S50 includes: forming gates and word lines. The gates cover the gate dielectric layers, and the gates together with the horizontal semiconductor layers form gating transistors. The word lines are perpendicularly arranged on the substrate along a third direction, and the word lines intersect the semiconductor channels of the gating transistors arranged along the third direction, and are connected to the gates of the gating transistors.

Step S60 includes: sequentially forming a resistive switching layer and an electrode layer on a side of each horizontal semiconductor layer away from the source line, where the resistive switching layer, the electrode layer, and the horizontal semiconductor layer jointly form a resistive switching component, and the gating transistor and the resistive switching component form a memory cell.

Step S70 includes: forming bit lines extending along the third direction, where the bit lines are connected to the electrode layers of the resistive switching components arranged along the third direction.

In the manufacturing method of the memory device according to the embodiment, the horizontal semiconductor layer 63 extending along the first direction X is formed, and the horizontally arranged gating transistor 21 is formed, so that a feature size of the gating transistor 21 can be reduced, and an occupied area of the gating transistor 21 can be reduced. The resistive switching layer 221 and the electrode layer 222 are sequentially formed on the side of the horizontal semiconductor layer 63 away from the source line 30, the resistive switching layer 221, the electrode layer 222, and the horizontal semiconductor layer 63 jointly form the resistive switching component 22, and the gating transistor 21 and the resistive switching component 22 share the horizontal semiconductor layer 63, so that a feature size of the memory cell 20 can be reduced, and integration density of the memory cells 20 can be improved. Meanwhile, the source line 30 formed in the embodiment extends along the second direction Y, the source line 30 is connected to the side of the horizontal semiconductor layer 63 away from the resistive switching layer 221; the word line 40 extends along the third direction Z, the word line 40 intersects the horizontal semiconductor layer 63 of the gating transistor 21; the bit line 50 extends along the third direction Z, and the bit line 50 is connected to the electrode layers 222 of the resistive switching components 22 arranged along the third direction Z; hence, the memory cells 20 can be integrated using the third direction perpendicular to the substrate 10, and integration density of the memory device 100 is enhanced.

The following describes in detail various steps of the manufacturing method of the memory device with reference to FIG. 8 to FIG. 28. FIG. 8 to FIG. 28, in combination with FIG. 2 to FIG. 6, are schematic structural diagrams of the memory device during a manufacturing process thereof according to an exemplary embodiment of the present disclosure.

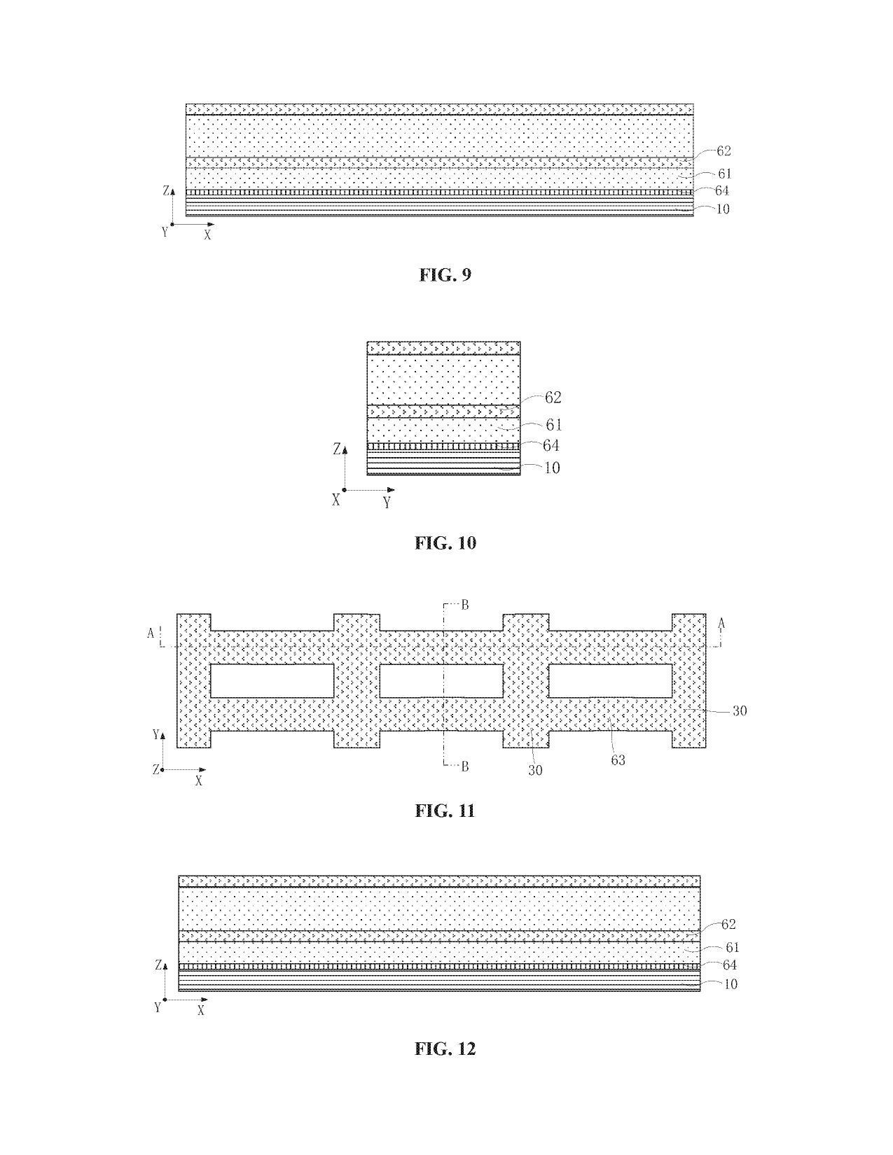

As shown in FIG. 8, FIG. 9, and FIG. 10, the substrate 10 may be a semiconductor substrate, and a material of the semiconductor substrate may include silicon (Si), silicon germanium (SiGe), silicon germanium carbon (SiGeC), silicon carbide (SiC), or other III/V semiconductor materials or II/VI semiconductor materials. Alternatively, for another example, the semiconductor substrate may be a layered substrate including, e.g., Si/SiGe, Si/SiC, silicon-on-insulator (SOI), or SiGe-on-insulator.

As shown in FIG. 8, FIG. 9, and FIG. 10, the insulating layers 61 and the semiconductor material layers 62 may be alternately deposited on the substrate 10 by chemical vapor deposition (CVD), atomic layer deposition (ALD) or physical vapor deposition (PVD).

A material of the insulating layers 61 may include at least one of silicon oxide (SiO₂), silicon nitride (Si₃N₄), aluminum oxide (Al₂O₃), hafnium oxide (HfO₂), tantalum oxide (Ta₂O₅), or zirconium oxide (ZrO₂).

A material of the semiconductor material layers 62 includes a semiconductor material such as silicon or metal oxide.

In some embodiments, the material of the semiconductor material layer 62 includes metal oxide. Thus, process compatibility between the formed gating transistor 21 and a subsequent CMOS process can be improved, the thermal budget cost can be reduced, and the product yield can be increased.

Exemplarily, the metal oxide may be indium gallium zinc oxide (IGZO). When the metal oxide is IGZO, a leakage current of the transistor is relatively small (the leakage current is less than or equal to 10⁻¹⁵A), thereby ensuring a low refresh rate of the memory. It should be noted that the metal oxide may alternatively be ITO, IWO, ZnOₓ, InOₓ, In₂O₃, InWO, SnO₂, TiOₓ, InSnOₓ, ZnₓO_{y}N_{z}, MgₓZn_{y}O_{z}, InₓZn_{y}O_{z}, InₓGa_{y}Zn_{z}Oₐ, ZrₓIn_{y}Zn_{z}Oₐ, HfₓIn_{y}Zn_{z}Oₐ, SnₓIn_{y}Zn_{z}Oₐ, AlₓSn_{y}In_{z}ZnₐO_{d}, SiₓIn_{y}Zn_{z}Oₐ, ZnₓSn_{y}O_{z}, AlₓZn_{y}Sn_{z}Oₐ, GaₓZn_{y}Sn_{z}Oₐ, ZrₓZn_{y}Sn_{z}Oₐ, InGaSiO, IAZO, IGO, IZO (indium-zinc-oxide), IZOₓ, or the like.

In some embodiments, as shown in FIG. 8, FIG. 9, and FIG. 10, before the alternating insulating layers 61 and semiconductor material layers 62 are formed on the substrate 10, an etch stop layer 64 is deposited on the substrate 10. The etch stop layer 64 is configured to protect the substrate 10 and prevent the substrate 10 from being damaged by over etching.

Exemplarily, a material of the etch stop layer 64 may include at least one of silicon oxide (SiO₂), silicon nitride (Si₃N₄), aluminum oxide (Al₂O₃), hafnium oxide (HfO₂), tantalum oxide (Ta₂O₅), or zirconium oxide (ZrO₂).

Exemplarily, the etch stop layer 64 may be deposited using CVD or ALD.

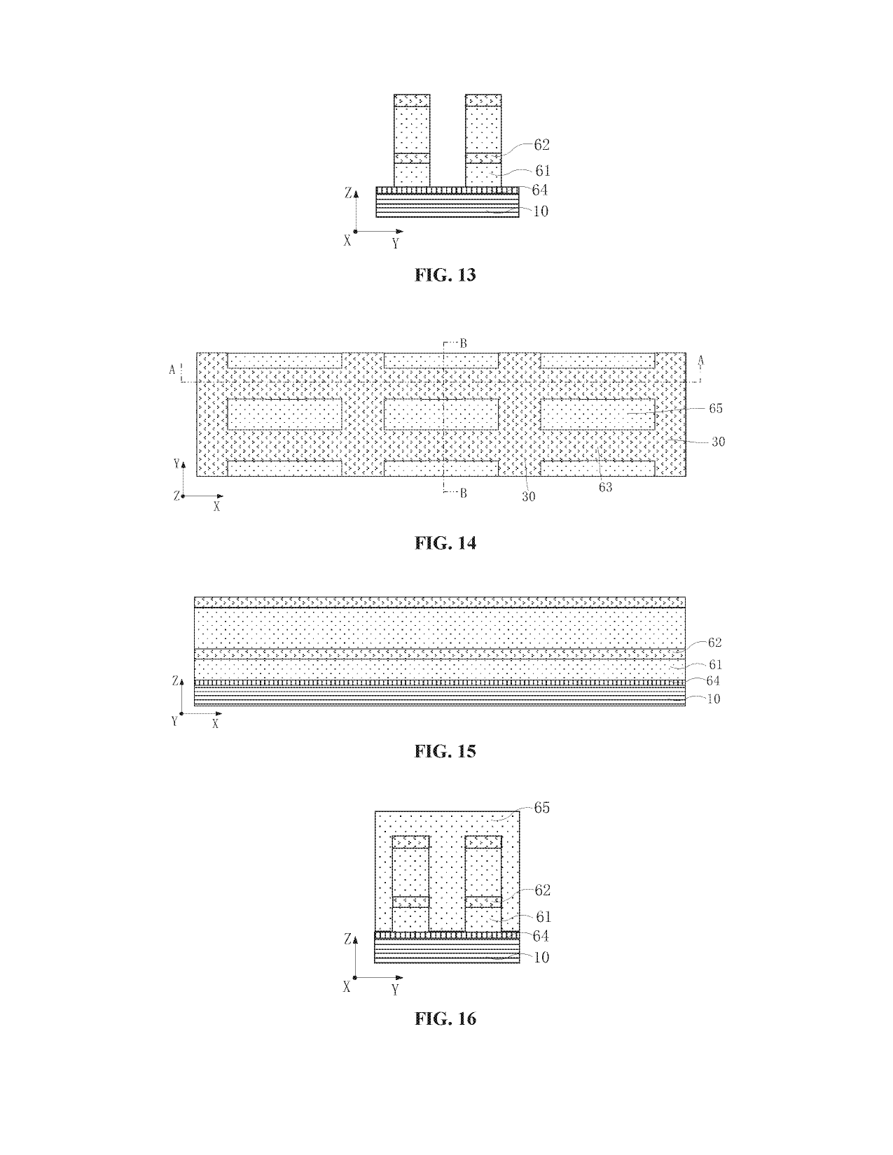

As shown in FIG. 11, FIG. 12, and FIG. 13, the insulating layers 61 and the semiconductor material layers 62 are etched layer by layer in a direction from a top layer of the alternating insulating layers 61 and semiconductor material layers 62 to the substrate 10, and the etching is stopped once a top surface of the substrate 10 is exposed. Each semiconductor material layer 62 is patterned to form the source line 30 extending in the second direction Y and the horizontal semiconductor layer 63 extending in the first direction X. Along the first direction X, at least one end of the horizontal semiconductor layer 63 is connected to the source line 30. From the end of the horizontal semiconductor layer 63 connected to the source line 30, the horizontal semiconductor layer 63 includes the first source/drain 211, the semiconductor channel 212, and the second source/drain 213 which are sequentially arranged along the first direction X. In some embodiments, along the first direction X, two ends of the horizontal semiconductor layer 63 are respectively connected to the source lines 30 on both sides , and the horizontal semiconductor layers 63 and the source lines 30 have a grid projection onto the substrate 10.

Exemplarily, the alternating insulating layers 61 and semiconductor material layers 62 may be etched using a dry process.

First, as shown in FIG. 14, FIG. 15, and FIG. 16, a first dielectric layer 65 is deposited by CVD to fill removed regions of the insulating layers 61 and the semiconductor material layers 62. The first dielectric layer 65 covers the exposed surface of the substrate 10 and fills positions between the insulating layers 61, between the source lines 30, and between the horizontal semiconductor layers 63, facilitating the performing of a subsequent manufacturing process.

Exemplarily, a material of the first dielectric layer 65 may include at least one of silicon oxide (SiO₂), silicon nitride (Si₃N₄), aluminum oxide (Al₂O₃), hafnium oxide (HfO₂), tantalum oxide (Ta₂O₅), or zirconium oxide (ZrO₂).

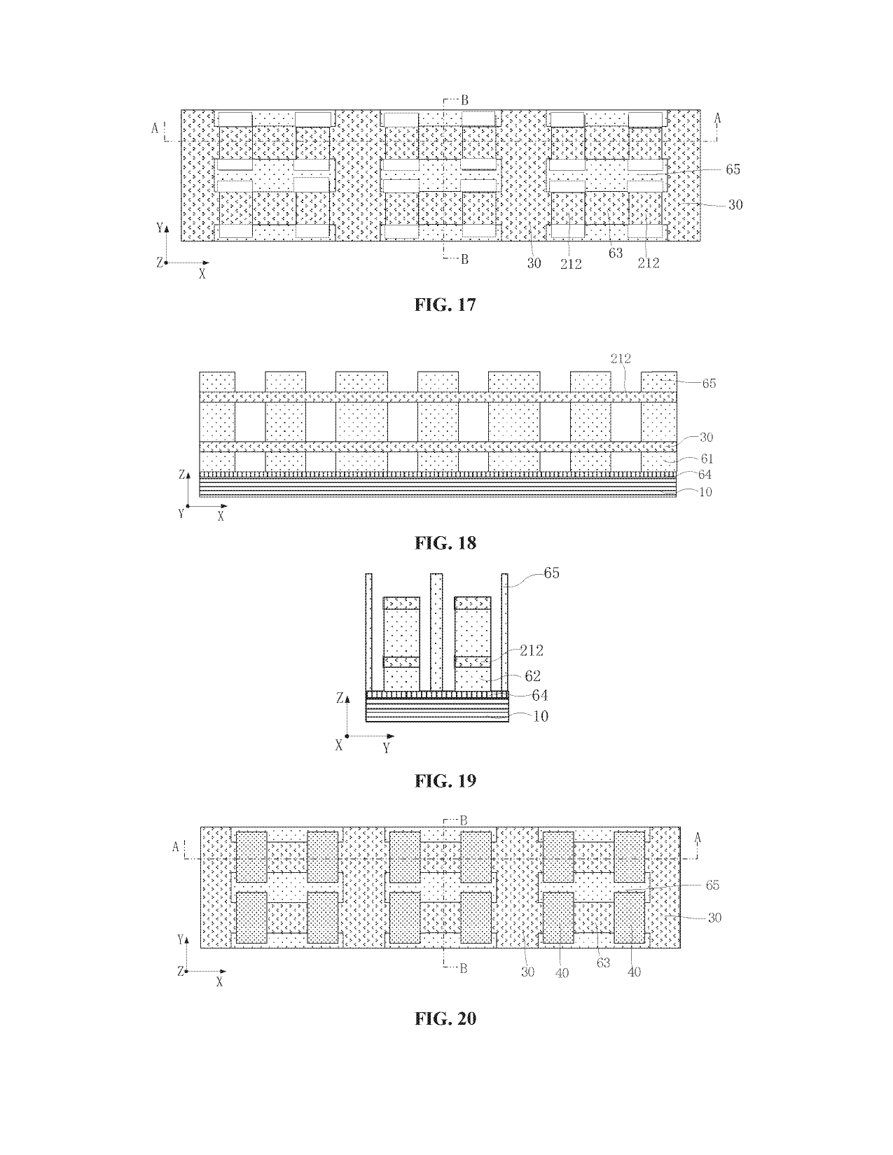

Then, a photoresist layer (not shown in the drawings) is formed on the first dielectric layer 65 and the alternating insulating layers 61 and semiconductor material layers 62, and exposure development is performed on the photoresist layer to form a mask pattern. As shown in FIG. 17, FIG. 18, and FIG. 19, referring to FIG. 1 to FIG. 6, the insulating layers 61 and the first dielectric layer 65 are etched according to the mask pattern, parts of the insulating layers 61 and the first dielectric layer 65 are removed, and the semiconductor channels 212 are exposed. The semiconductor channel 212 is located in a middle region of the horizontal semiconductor layer 63, and after the semiconductor channel 212 is exposed, along the first direction X, the first source/drain 211 and the second source/drain 213 located at two sides of the semiconductor channel 212 are still covered by the insulating layer 61. Along the third direction Z, the semiconductor channels 212 of the horizontal semiconductor layers 63 are suspended.

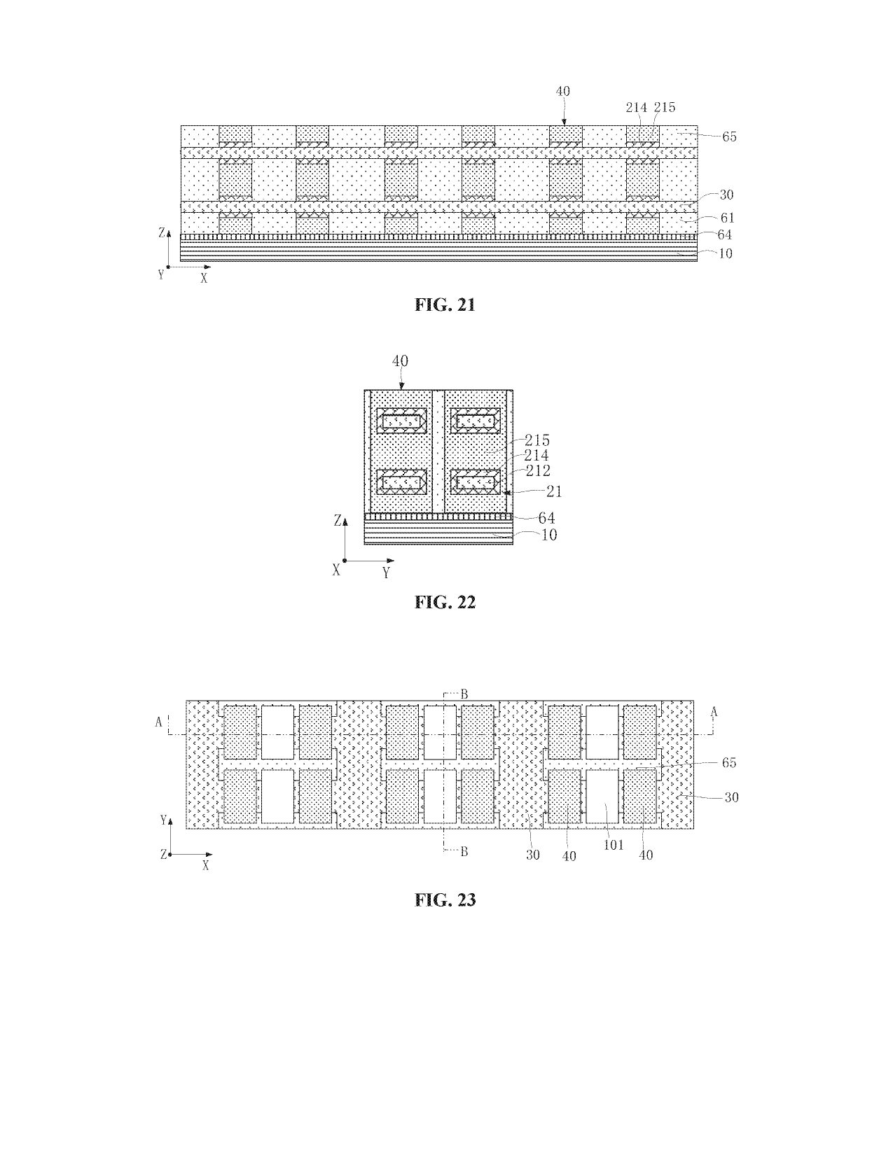

Referring to FIG. 20, FIG. 21, and FIG. 22, in combination with FIG. 1 to FIG. 6, a gate dielectric layer 214 may be formed on the exposed surface of each semiconductor channel 212 using at least one of an in-situ steam generation (ISSG) process, an atomic layer deposition process, a plasma vapor deposition process, or a rapid thermal oxidation (RTO) process. In a plane perpendicular to the first direction X, the gate dielectric layer 214 surrounds and covers the semiconductor channel 212.

Exemplarily, a material of the gate dielectric layer 214 includes at least one of silicon oxide (SiO₂), silicon nitride (Si₃N₄), aluminum oxide (Al₂O₃), hafnium oxide (HfO₂), tantalum oxide (Ta₂O₅), or zirconium oxide (ZrO₂).

Still referring to FIG. 20, FIG. 21, FIG. 22 and in combination with FIG. 1 to FIG. 6, a conductive material may be deposited by a chemical vapor deposition process, an atomic layer deposition process or a physical vapor deposition process. The conductive material covers the gate dielectric layers 214 and fills unfilled regions between the semiconductor channels 212, to form gates 215 of the gating transistors 21 and form the word lines 40 perpendicularly arranged on the substrate 10 along the third direction Z. In the plane perpendicular to the first direction X, the gate 215 of the gating transistor 21 surrounds and covers the gate dielectric layer 214. The gate 215, the gate dielectric layer 214, and the first source/drain 211, the semiconductor channel 212, and the second source/drain 213 formed in the horizontal semiconductor layer 63 together form the gating transistor 21.

The gating transistor 21 formed in the embodiment is a gate-all-around transistor with a horizontal channel, and in this way, the gating transistor 21 may have a smaller feature size, which is beneficial to further reducing the size of the memory cell 20, improving the integration density of the memory cells 20, and improving a utilization rate of a usable area of the substrate 10. The word line 40 is connected to the gates 215 of the gating transistors 21 arranged along the third direction Z.

Exemplarily, a material of the word line 40 may include at least one of Ti, TiN, Ta, TaN, Al, AlN, W, Cu, Pt, Mo, Ni, Ir, Ru, ITO, or heavily doped polysilicon.

In some embodiments, after the horizontal semiconductor layer 63 and the source line 30 are formed, along the first direction X, both ends of the horizontal semiconductor layer 63 are respectively connected to the source line 30. Sequentially forming the resistive switching layer 221 and the electrode layer 222 on a side of the horizontal semiconductor layer 63 away from the source line 30 includes the following steps.

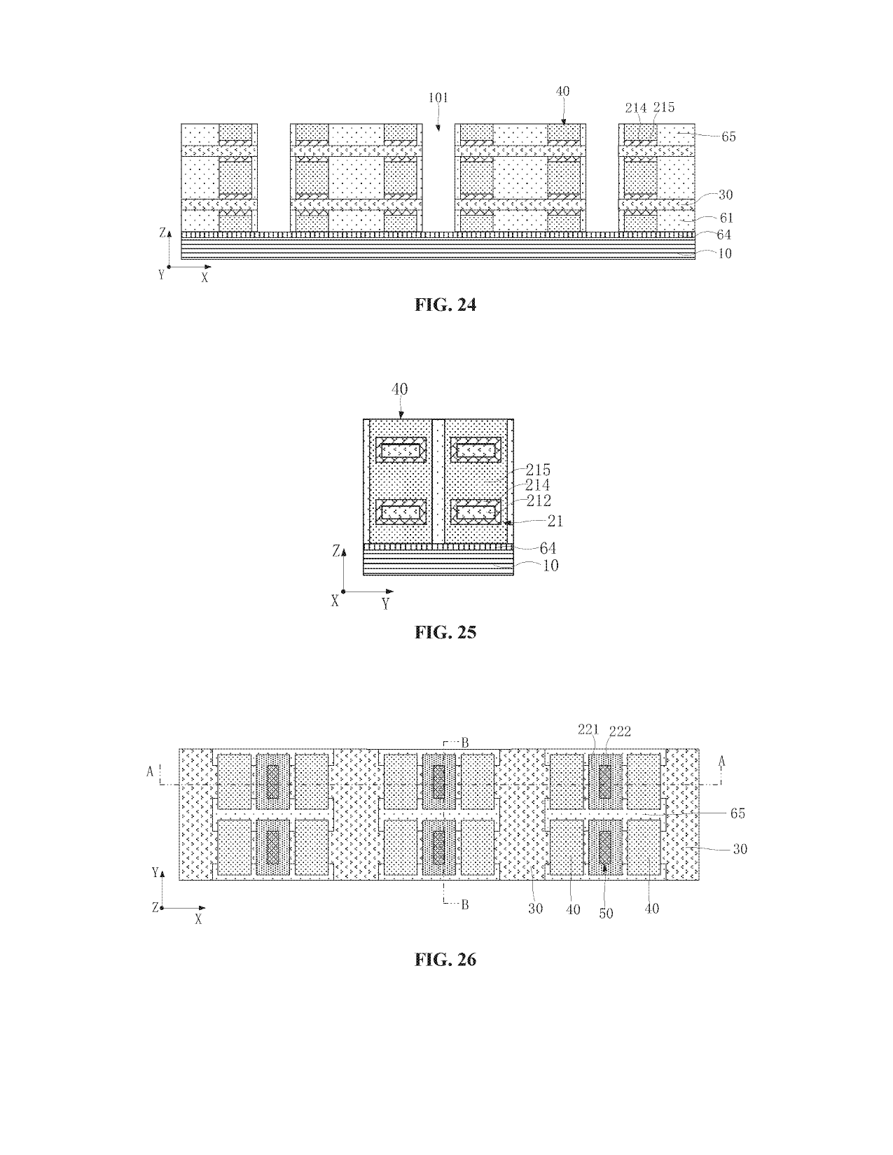

Referring to FIG. 23, FIG. 24, and FIG. 25, in combination with FIG. 1 to FIG. 6, the alternating insulating layers 61 and horizontal semiconductor layers 63 are etched to form the electrode layer 222 penetrating through the alternating insulating layers 61 and horizontal semiconductor layers 63. The electrode layer 222 divides the horizontal semiconductor layer 63 into a first section and a second section which are spaced apart along the first direction X. The first section is configured to form the first memory cell 120, the second section is configured to form the second memory cell 220, and the first memory cell 120 and the second memory cell 220 are in mirror symmetry with respect to the bit line 50.

Referring to FIG. 26, FIG. 27, and FIG. 28, in combination with FIG. 1 to FIG. 6, the resistive switching layer 221 is formed. The resistive switching layer 221 covers a side wall of the electrode layer 222. The resistive switching layer 221 may be formed using ALD.

Exemplarily, the resistive switching layer 221 may have a single-layer or multi-layer structure. A material of the resistive switching layer 221 includes TaOₓ, TiOₓ, HfOₓ, ZrOₓ, SiOₓ, MgO, AlNₓ, GeTeₓ, GeSb, GeTe, SbTe, CuSₓ, GeSₓ, GeSeₓ, ZnS, AlBO, SrTiOₓ, ZrTiOₓ, BaTiOₓ, HfZrO, or HfAlO.

Referring to FIG. 26, FIG. 27, and FIG. 28, in combination with FIG. 1 to FIG. 6, the electrode layer 222 is formed. The electrode layer 222 covers an inner side wall of the resistive switching layer 221 and fills an unfilled region on an inner side of the resistive switching layer 221. The electrode layer 222 may be formed by ALD or CVD, and the electrode layer 222 covers the inner side wall of the resistive switching layer 221. Meanwhile, the bit line 50 extending along the third direction Z is formed on the substrate 10.

In the embodiment, the resistive switching layer 221 and the electrode layer 222 are both perpendicularly arranged on the substrate 10 along the third direction Z, the resistive switching layer 221 includes a resistive switching region and a non-resistive switching region spaced apart along the third direction Z, and the horizontal semiconductor layer 63 is connected to the resistive switching region of the resistive switching layer 221. The horizontal semiconductor layer 63, the connected resistive switching layer 221, and the electrode layer 222 form the resistive switching component 22, and the gating transistor 21 and the resistive switching component 22 together form the memory cell 20.

In an embodiment, a first trench 101 is formed, the resistive switching layer 221 and the electrode layer 222 are sequentially formed in the first trench 101, so that the circumferential surface of the electrode layer 222 is covered by the resistive switching layer 221 in a plane parallel to the substrate 10. Therefore, a contact area between the resistive switching layer 221 and the electrode layer 222 of the resistive switching component 22 is larger, so that a driving current of the resistive switching layer 221 can be reduced, and the resistive switching layer 221 can be driven by a smaller driving current to change a resistance value of the resistive switching layer 221, thereby completing a read-write operation. In this way, the memory cell 20 may have a smaller feature size, which facilitates further miniaturization and small size of the memory device 100.

In the manufacturing method of the memory device according to the embodiment, the horizontal semiconductor layer 63 with two ends connected to the source lines 30 is formed; the first trench 101 is formed to divide the horizontal semiconductor layer 63 into the first section and the second section spaced apart along the first direction X; the bit line 50 is formed, the first memory cell 120 and the second memory cell 220 with the bit line 50 as a mirror center are formed on the two sides of the bit line 50, and the first memory cell 120 and the second memory cell 220 share the bit line 50. Meanwhile, the bit line 50 extends along the third direction Z, and the bit line 50 is shared by multiple first memory cells 120 arranged along the third direction Z and multiple second memory cells 220 arranged along the third direction Z. Hence, the integration density of the memory cells 20 is further improved, the utilization rate of the usable area of the substrate 10 is enhanced, and meanwhile, manufacturing difficulty of the memory device 100 can be reduced, manufacturing processes are saved, and it is beneficial to reducing the production cost and increasing the product yield.

In the manufacturing method of the memory device according to the embodiment, the first memory cell 120 and the second memory cell 220 with the bit line 50 as the mirror center are formed, the first memory cell 120 and the second memory cell 220 are arranged along the first direction X, and one column of first memory cells 120 arranged along the second direction Y and one column of second memory cells 220 arranged along the second direction Y on both sides of the source line 30 share the same source line 30, which further improves the integration density of the memory cells 20, enhances the utilization rate of the usable area of the substrate 10, and meanwhile can reduce the manufacturing difficulty of the memory device 100, save the manufacturing processes, and be beneficial to reducing the production cost and increasing the product yield.

In some other embodiments, the step S60 of sequentially forming the resistive switching layer and the electrode layer on the side of each horizontal semiconductor layer away from the source line includes the following steps:

step S601: forming a first trench on a side of the second source/drain of the horizontal semiconductor layer away from the source line, the first trench being arranged on the substrate along the third direction;

step S602: forming the resistive switching layer, the resistive switching layer covering a side wall of the first trench; and

step S603: forming the electrode layer, the electrode layer covering an inner side wall of the resistive switching layer and filling an unfilled region of the first trench.

According to an embodiment, which is not shown in the drawings, after the horizontal semiconductor layer 63 and the source lines 30 are formed, in the first direction X, one end of the horizontal semiconductor layer 63 is connected to the source line 30 on one side of the horizontal semiconductor layer 63, and the other end of the horizontal semiconductor layer 63 is spaced apart from the source line 30 on the other side of the horizontal semiconductor layer 63. In the embodiment, the first dielectric layer 65 on the side of the horizontal semiconductor layer 63 away from the source line 30 is etched until a top surface of the substrate 10 is exposed, and the first trench 101 penetrating through the first dielectric layer 65 along the third direction Z is formed. Then, the resistive switching layer 221 and the electrode layer 222 are sequentially formed in the first trench 101, and the formation manner of the resistive switching layer 221 and the electrode layer 222 is the same as that of the above embodiments, so it is not repeated herein.

It should be understood that, although the steps in FIG. 7 and the foregoing flow are shown in sequence as indicated by the arrows or the step sequence, the steps are not necessarily performed in sequence as indicated by the arrows. Unless explicitly stated herein, the steps are not limited to being performed in the exact order and may be performed in other orders. At least part of the steps in FIG. 7 and the foregoing flow may include multiple sub-steps or multiple stages, which are not necessarily performed at the same moment, but may be performed at different moments, and the sub-steps or the stages are not necessarily performed in sequence, but may be performed alternately with other steps or at least part of the sub-steps or the stages in other steps.

The manufacturing orders of the memory cells, the word lines, the bit lines, and the source lines in the foregoing embodiment can be exchanged randomly or combined mutually. Therefore, those skilled in the art can combine and/or exchange any plurality of the manufacturing flows of the memory cells, the word lines, the bit lines, and the source lines without creative efforts, and all of them should belong to the protection scope of the embodiments of the present disclosure.

In some embodiments, there is provided an electronic device, including the memory according to any one of the embodiments of the present disclosure. The electronic device is, for example, but not limited to, a consumer electronic product, a home electronic product, a vehicle-mounted electronic product, a financial terminal product, or the like, of a suitable type. The consumer electronic product is, for example, a mobile phone, a tablet computer, a notebook computer, a desktop display, an all-in-one computer, or the like. The home electronic product is, for example, an intelligent door lock, a television, a refrigerator, a wearable device, or the like. The vehicle-mounted electronic product is, for example, a vehicle-mounted navigator, a vehicle-mounted DVD, or the like. The financial terminal product is, for example, an ATM machine, a terminal for self-service transaction, or the like.

It will be understood by those skilled in the art that all or part of the processes of the method according to the embodiments described above may be implemented by a computer program instructing related hardware, and the computer program may be stored in a non-transitory computer-readable storage medium, and when executed, may include the processes of the embodiments directed to the method described above. Any reference to memories, databases or other media used in the embodiments of the present application can include at least one of a non-transitory memory or a transitory memory. The non-transitory memory may include a read-only memory (ROM), a magnetic tape, a floppy disk, a flash memory, an optical memory, a high-density embedded non-transitory memory, a resistive random access memory (ReRAM), a magneto-resistive random access memory (MRAM), a ferroelectric random access memory (FRAM), a phase change memory (PCM), a graphene memory, or the like. The transitory memory can include a random access memory (RAM), an external cache memory, or the like. The databases involved in the embodiments of the present application may include at least one of relational database or non-relational database. The non-relational database may include, but is not limited to, a block chain-based distributed database, or the like. The processors referred to in the embodiments of the present application may include, but are not limited to, general processors, central processors, graphics processors, digital signal processors, programmable logic units, data processing logic units based on quantum calculations, or the like. The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the specification.

It should be noted that the above-described embodiments are for illustrative purposes only and are not intended to limit the present disclosure.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the specification.

The above-described embodiments are only several implementations of the present application, and the descriptions are relatively specific and detailed, but they should not be construed as limiting the scope of the present application. It should be understood by those of ordinary skill in the art that various modifications and improvements can be made without departing from the concept of the present application, and all fall within the protection scope of the present application. Therefore, the protection scope of the present application should be subject to the appended claims.

What is claimed is:

1. A memory device, comprising:
memory cells arranged on a substrate, wherein the memory cells are arranged at intervals along a direction perpendicular to the substrate, and each of the memory cells comprises a gating transistor and a resistive switching component; wherein the gating transistor comprises a horizontal semiconductor layer extending along a first direction parallel to the substrate, and the resistive switching component comprises the horizontal semiconductor layer, and a resistive switching layer and an electrode layer which are sequentially arranged away from the horizontal semiconductor layer in the first direction;
source lines each extending along a second direction parallel to the substrate and arranged at intervals along a third direction perpendicular to the substrate, wherein the first direction intersects the second direction; wherein along the first direction, the source line is arranged on a side of the horizontal semiconductor layer away from the resistive switching layer;
a word line arranged along the third direction, wherein the word line intersects the horizontal semiconductor layers of the gating transistors arranged along the third direction; and
a bit line arranged along the third direction, wherein the bit line is connected to the electrode layers of the resistive switching components arranged along the third direction.

2. The memory device according to claim 1, wherein in the memory cells arranged along the third direction, the resistive switching layers of the resistive switching components are sequentially connected.

3. The memory device according to claim 1, wherein the resistive switching layer surrounds a circumferential surface of the electrode layer.

4. The memory device according to claim 1, wherein the gating transistor comprises:
a first source/drain, a semiconductor channel, and a second source/drain, wherein the first source/drain, the semiconductor channel, and the second source/drain are sequentially arranged at the horizontal semiconductor layer along a direction away from the source line;
a gate dielectric layer arranged between the word line and the semiconductor channel, wherein in a plane perpendicular to the first direction, the gate dielectric layer surrounds the semiconductor channel; and
a gate, wherein in a plane perpendicular to the first direction, the gate surrounds the gate dielectric layer, and wherein the gate is connected to the word line.

5. The memory device according to claim 1, wherein the memory cells are arranged along the first direction and the second direction; and
along the first direction, one side of the bit line is connected to a first memory cell, the other side of the bit line is connected to a second memory cell, and the first memory cell and the second memory cell are in mirror symmetry with respect to the bit line.

6. The memory device according to claim 5, wherein in the first direction, the first memory cell and the second memory cell are located on both sides of the source line, and the first memory cell and the second memory cell share the same source line.

7. A manufacturing method of a memory device, comprising:
providing a substrate, and forming alternating insulating layers and semiconductor material layers on the substrate;
patterning the alternating insulating layers and semiconductor material layers, wherein the semiconductor material layers form horizontal semiconductor layers and source lines, the horizontal semiconductor layers each extend along a first direction, the source lines each extend along a second direction, the first direction and the second direction are parallel to the substrate, and the first direction intersects the second direction; wherein along the first direction, at least one end of each horizontal semiconductor layer is connected to the source line, and the horizontal semiconductor layer comprises a first source/drain, a semiconductor channel, and a second source/drain which are sequentially arranged in a direction away from the source line;
removing a part of the insulating layers to expose the semiconductor channels;
forming gate dielectric layers to cover the semiconductor channels;
forming gates and word lines, wherein the gates cover the gate dielectric layers and form gating transistors together with the horizontal semiconductor layers, the word lines are perpendicularly arranged on the substrate along a third direction, and the word lines intersect the semiconductor channels of the gating transistors arranged along the third direction, and are connected to the gates of the gating transistors;
sequentially forming a resistive switching layer and an electrode layer on a side of each horizontal semiconductor layer away from the source line, wherein the resistive switching layer, the electrode layer, and the horizontal semiconductor layer jointly form a resistive switching component, and the gating transistor and the resistive switching component form a memory cell; and
forming bit lines extending along the third direction, wherein the bit lines are connected to the electrode layers of the resistive switching components arranged along the third direction.

8. The manufacturing method of the memory device according to claim 7, wherein sequentially forming the resistive switching layer and the electrode layer on the side of each horizontal semiconductor layer away from the source line comprises:
forming a first trench on a side of the second source/drain of the horizontal semiconductor layer away from the source line, the first trench being arranged on the substrate along the third direction;
forming the resistive switching layer, the resistive switching layer covering a side wall of the first trench; and
forming the electrode layer, the electrode layer covering an inner side wall of the resistive switching layer and filling an unfilled region of the first trench.

9. The manufacturing method of the memory device according to claim 7, wherein after the horizontal semiconductor layer and the source lines are formed, along the first direction, two ends of the horizontal semiconductor layer are respectively connected to the source lines; and wherein the manufacturing method comprises:
etching the alternating insulating layers and horizontal semiconductor layers to form the first trench penetrating through the alternating insulating layers and horizontal semiconductor layers, the first trench dividing the horizontal semiconductor layer into a first section and a second section which are spaced apart along the first direction;
wherein the first section is configured to form the first memory cell, the second section is configured to form the second memory cell, and the first memory cell and the second memory cell are in mirror symmetry with respect to the bit line.

10. An electronic device, comprising the memory device according to claim 1.

11. An electronic device, comprising a memory device manufactured by the manufacturing method of the memory device according to claim 7.
